(19) United States
(12) Patent Application Publication
(10) Pub. No.: US 2025/0149494 A1
(43) Pub. Date: May 8, 2025

(54) SEMICONDUCTOR PACKAGE AND METHOD OF MANUFACTURING THE SAME

(71) Applicant: SAMSUNG ELECTRONICS CO., LTD., Suwon-si (KR)

(72) Inventors: Jaekyung Yoo, Suwon-si (KR); Jinwoo Park, Suwon-si (KR); Kyonghwan Koh, Suwon-si (KR); Woohyeong Kim, Suwon-si (KR); Taeryong Kim, Suwon-si (KR)

(73) Assignee: SAMSUNG ELECTRONICS CO., LTD., Suwon-si (KR)

(21) Appl. No.: 18/940,264

(22) Filed: Nov. 7, 2024

(30) Foreign Application Priority Data
Nov. 7, 2023 (KR) 10-2023-0153099

(51) Int. Cl. H01L 23/00; H01L 21/56; H01L 23/29; H01L 23/48; H01L 23/498; H01L 25/065; H01L 25/10; H01L 25/18; H10B 80/00

(52) U.S. Cl. CPC H01L 24/29; H01L 23/295; H01L 23/481; H01L 23/49833; H01L 23/49838; H01L 24/14; H01L 24/16; H01L 24/32; H01L 24/73; H01L 21/565; H01L 25/0652; H01L 25/105; H01L 25/18; H01L 2224/14131; H01L 2224/16145; H01L 2224/16225; H01L 2224/29007; H01L 2224/29017; H01L 2224/29018; H01L 2224/29298; H01L 2224/32225; H01L 2224/73204; H01L 2225/1023; H01L 2225/1041; H01L 2924/14361; H01L 2924/365; H10B 80/00

(57) ABSTRACT

A semiconductor package includes a first substrate, a first semiconductor chip on an upper surface of the first substrate, a first bump between the first substrate and the first semiconductor chip, a first underfill layer that fills a center portion of a space between the first substrate and the first semiconductor chip, and a first molding member that covers an upper surface and side surfaces of the first semiconductor chip, and fills a periphery portion of the space between the first substrate and the first semiconductor chip, wherein a volume occupied by the first molding member in the space between the first substrate and the first semiconductor chip is greater than a volume occupied by the first underfill layer in the space between the first substrate and the first semiconductor chip.

### CROSS-REFERENCE TO RELATED APPLICATION

This application is based on and claims priority under 35 U.S.C. § 119 to Korean Patent Application No. 10-2023-0153099, filed on Nov. 7, 2023, in the Korean Intellectual Property office, the disclosure of which is incorporated by reference herein in its entirety.

### BACKGROUND

The present disclosure relate to a semiconductor package and a method of manufacturing the semiconductor package, and more particularly, to a semiconductor package with improved reliability and a method of manufacturing the semiconductor package.

Recently, a demand for portable devices has been rapidly increasing in the electronic products market, and accordingly, miniaturization and light weight of electronic components mounted on the electronic products are continuously required. In order to miniaturize electronic components and make them light weight, semiconductor packages mounted thereon are required to process a large amount of data while defects of the semiconductor packages are decreased.

At this time, a molding process of molding a semiconductor chip with sealing resin such as epoxy molding compound (EMC) is performed to prevent the semiconductor chip from being damaged by external impact, light, etc. In a trend where the thickness of a semiconductor package is gradually decreasing, the size of the space between the semiconductor chip and a substrate is also decreasing, and accordingly, an issue of voids generated in the space has emerged.

### SUMMARY

Embodiments of the disclosure provide a semiconductor package reducing voids generated between a first semiconductor chip and a first substrate, and a method of manufacturing the semiconductor package, are provided.

In addition, problems solved by embodiments of the present disclosure are not limited to those mentioned above, and other problems that are solved by embodiments of the present disclosure may be clearly understood by those of ordinary skill in the art from the following descriptions.

According to an aspect of an embodiment, a semiconductor package is provided and includes: a first substrate; a first semiconductor chip on an upper surface of the first substrate; at least one first bump between the first substrate and the first semiconductor chip, the at least one first bump configured to electrically connect the first substrate to the first semiconductor chip; a first underfill layer that fills a center portion of a space between the first substrate and the first semiconductor chip; and a first molding member that covers an upper surface and side surfaces of the first semiconductor chip, and fills a periphery portion of the space between the first substrate and the first semiconductor chip, wherein a volume occupied by the first molding member in the space between the first substrate and the first semiconductor chip is greater than a volume occupied by the first underfill layer in the space between the first substrate and the first semiconductor chip.

According to an aspect of an embodiment, a semiconductor package is provided and includes: a first substrate; a first semiconductor chip on an upper surface of the first substrate; at least one first bump between the first substrate and the first semiconductor chip, and configured to electrically connect the first substrate to the first semiconductor chip, the at least one first bump having a thickness in a vertical direction equal to or less than 10 μm; a first underfill layer that fills a center portion of a space between the first substrate and the first semiconductor chip; and a first molding member that covers an upper surface and side surfaces of the first semiconductor chip, and fills a periphery portion of the space between the first substrate and the first semiconductor chip, wherein a volume occupied by the first molding member in the space between the first substrate and the first semiconductor chip is greater than a volume occupied by the first underfill layer in the space between the first substrate and the first semiconductor chip, and wherein the volume occupied by the first underfill layer in the space between the first substrate and the first semiconductor chip is in a range of 5% to 50% of the space, excluding a volume of the space occupied by the at least one first bump.

According to an aspect of an embodiment, a semiconductor package is provided and includes: a first substrate including a wiring and an insulating layer surrounding the wiring; a first semiconductor chip on an upper surface of the first substrate; at least one first bump between the first substrate and the first semiconductor chip, and configured to electrically connect the first substrate to the first semiconductor chip, each of the at least one first bump having a thickness in a vertical direction equal to or less than 10 μm; a first underfill layer that fills a center portion of a space between the first substrate and the first semiconductor chip; and a first molding member that covers an upper surface and side surfaces of the first semiconductor chip, and fills a periphery portion of the space between the first substrate and the first semiconductor chip, wherein each of the first molding member and the first underfill layer includes a filler, a filler content of the first molding member is in a range of 70% to 90%, and a filler content of the first underfill layer is in a range of 5% to 40%, wherein a volume occupied by the first molding member in the space between the first substrate and the first semiconductor chip is greater than a volume occupied by the first underfill layer, and wherein the volume occupied by the first underfill layer in the space between the first substrate and the first semiconductor chip is in a range of 5% to 50% of the space, excluding a volume of the space occupied by the at least one first bump.

According to an aspect of an embodiment, a method of manufacturing a semiconductor package is provided and includes: preparing a carrier substrate; attaching a first substrate on the carrier substrate; arranging a first semiconductor chip on an upper surface of the first substrate; forming a first structure by arranging, on the upper surface of the first substrate, a first underfill ball adjacent to a sidewall of the first semiconductor chip; providing the first structure to a molding device; and compressing a first molding ball onto the first structure by closing the molding device, wherein, after the compressing the first molding ball, a volume of the first underfill ball within the space is less than a volume of the first molding ball within the space.

### BRIEF DESCRIPTION OF THE DRAWINGS

The above and other aspects will be more clearly understood from the following detailed description taken in conjunction with the accompanying drawings in which:

FIG. 1A is a schematic cross-sectional view of a semiconductor package according to an embodiment;

FIG. 1B is a cross-sectional view of a semiconductor package taken along line X1-X1′ in FIG. 1A;

FIG. 2 is a schematic cross-sectional view of a semiconductor package according to an embodiment;

FIG. 3A is a schematic cross-sectional view of a semiconductor package according to an embodiment;

FIG. 3B is an enlarged diagram of a region AA in FIG. 3A;

FIG. 4A is a schematic cross-sectional view of a semiconductor package according to an embodiment;

FIG. 4B is an enlarged diagram of a region BB in FIG. 4A; and

FIGS. 5 through 12 are schematic cross-sectional views illustrating a method of manufacturing a semiconductor package, according to embodiments.

### DETAILED DESCRIPTION

Hereinafter, non-limiting example embodiments of the present disclosure are described in detail with reference to the accompanying drawings. Identical reference numerals are used for the same constituent elements in the drawings, and duplicate descriptions thereof may be omitted.

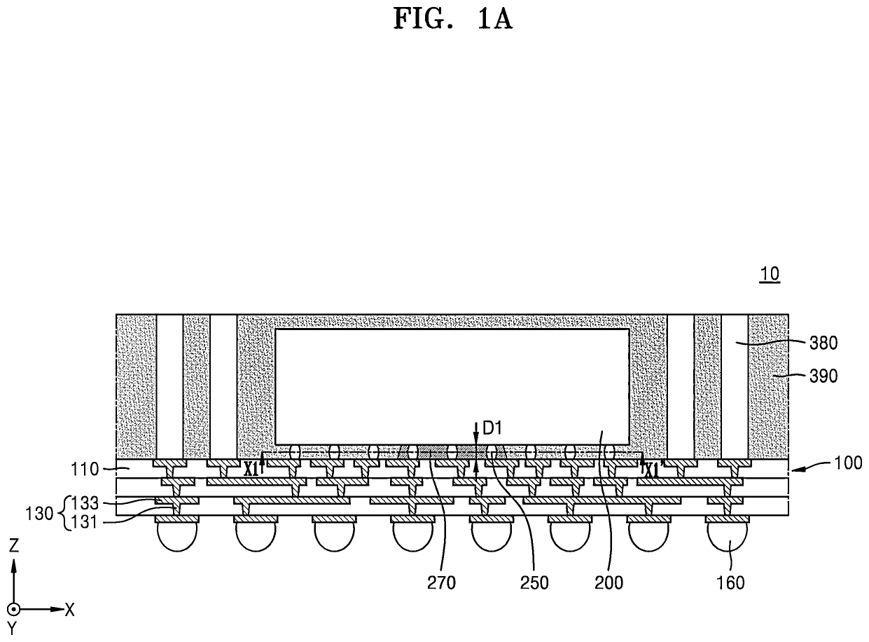

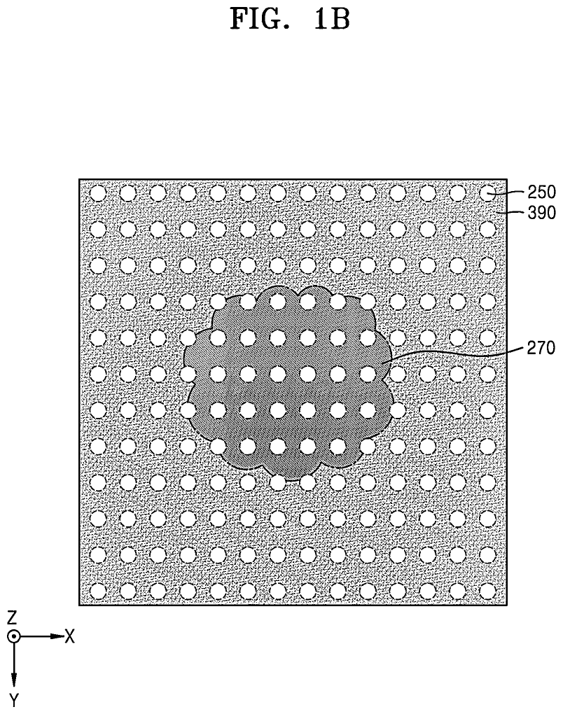

FIG. 1A is a schematic cross-sectional view of a semiconductor package 10 according to an embodiment. FIG. 1B is a cross-sectional view of the semiconductor package 10 taken along line X1-X1′ in FIG. 1A.

Referring to FIGS. 1A and 1B, the semiconductor package 10 may include a first substrate 100, a first semiconductor chip 200, a conductive pillar 380, a first underfill layer 270, and a first molding member 390.

The first substrate 100 may be electrically connected to each of the first semiconductor chip 200, the conductive pillar 380, and an external connection terminal 160 and may include an insulating layer 110 surrounding a wiring 130 and an insulating layer 110 surrounding the wiring 130. In some embodiments, at least one from among an upper surface and a lower surface of the first substrate 100 may have a flat shape.

Hereinafter, in the drawings, an X-axis direction and a Y-axis direction may represent directions in parallel with the upper surface or the lower surface of the first substrate 100, and the X-axis direction and the Y-axis direction may be perpendicular to each other. A Z-axis direction may represent a direction perpendicular to the upper surface or the lower surface of the first substrate 100. In other words, the Z-axis direction may include a direction perpendicular to an X-Y plane.

In addition, below, a first horizontal direction, a second horizontal direction, and a vertical direction in the drawings may be understood as follows. The first horizontal direction may be understood as the X-axis direction, the second horizontal direction may be understood as the Y-axis direction, and the vertical direction may be understood as the Z-axis direction.

The wiring 130 may be formed to penetrate one or more of the insulating layer 110 from the upper surface to the lower surface of the first substrate 100, and the insulating layers 110 surrounding the wiring 130 may be stacked on each other in a vertical direction Z. In this case, the wiring 130 may function as an electrical connection path penetrating the first substrate 100 from the upper surface to the lower surface of the first substrate 100. The first semiconductor chip 200, the conductive pillar 380, and the external connection terminal 160 may be electrically connected to each other via the wiring 130 of the first substrate 100.

In some embodiments, the first substrate 100 may include a ceramic substrate, a printed circuit board (PCB), or an organic substrate. In this case, the wiring 130 may include copper, nickel, stainless steel, or beryllium copper, and the insulating layer 110 may include at least one material selected from Frame Retardant 4 (FR-4), tetrafunctional epoxy, polyphenylene ether, epoxy/polyphenylene oxide, bismaleimide triazine (BT), Thermount, cyanate ester, polyimide, and liquid crystal polymer.

In some embodiments, the first substrate 100 may include a rewiring structure formed by using a rewiring process. In this case, the wiring 130 of the first substrate 100 may be understood as a rewiring pattern, and the insulating layer 110 of the first substrate 100 may be understood as a rewiring insulating layer. In this case, the wiring 130 may include a metal, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), or a combination thereof, but is not limited thereto, and in some embodiments, the wiring 130 may be formed by stacking a metal or an alloy of metals on a seed layer including Cu, Ti, titanium nitride, or titanium tungsten. In addition, the insulating layer 110 may be formed of, for example, photo imageable dielectric (PID) or photosensitive polyimide (PSPI).

The wiring 130 may include line patterns 133 and via patterns 131. The line patterns 133 may have a shape extending in a horizontal direction along at least one from among an upper surface and a lower surface of each of the plurality of insulating layers 110 stacked in the vertical direction Z. The via patterns 131 may have a shape extending and penetrating the insulating layer 110 in the vertical direction Z. The via patterns 131 may electrically connect together the line patterns 133 at different vertical levels. In some embodiments, at least some of the line patterns 133 may be formed together with some of the via patterns 131 into one body.

The first semiconductor chip 200 may be arranged on the upper surface of the first substrate 100. According to some embodiments, the first semiconductor chip 200 may include a memory chip. The memory chip may include, for example, a volatile memory chip, such as dynamic random access memory (RAM) (DRAM) and static RAM (SRAM), or a non-volatile memory chip, such as phase-change RAM (PRAM), magneto-resistive RAM (MRAM), ferroelectric RAM (FeRAM), and resistive RAM (RRAM). In addition, the first semiconductor chip 200 may include a logic chip. The logic chip may include, for example, a microprocessor, such as a central processing unit (CPU), a graphics processing unit (GPU), and an application processor (AP), an analog device, or a digital signal processor. However, the first semiconductor chip 200 is not limited to a memory chip or a logic chip, and the first semiconductor chip 200 may also have a chip structure including both a memory chip and a logic chip.

The first semiconductor chip 200 may be mounted on the first substrate 100 by using a first bump 250 in a flip chip manner. The first semiconductor chip 200 may be electrically connected to the first substrate 100 via the first bump 250. The first bump 250 may be physically in contact with each of a pad formed on the upper surface of the first substrate 100 and a pad formed under the lower surface of the first semiconductor chip 200, and may be electrically connected to the first substrate 100 and the first semiconductor chip 200.

According to some embodiments, the first bump 250 may have a pillar structure or a ball structure, or include a solder layer. According to some embodiments, the first bump 250 may include a micro bump. In this case, the micro bump may be understood as a bump having a critical dimension of less than about 20 μm. For example, when the first bump 250 has a spherical shape, the diameter of the first bump 250 may be less than about 20 μm.

The first bump 250 may be provided in plural. A plurality of first bumps 250 may be provided apart from each other in a first horizontal direction X. According to some embodiments, a distance from the center of any one first bump 250 to the center of another first bump 250 directly adjacent thereto may be less than about 50 μm. According to some embodiments, a distance from the center of any one first bump 250 to the center of another first bump 250 directly adjacent thereto may be in a range of about 10 μm to about 50 μm.

The first substrate 100 and the first semiconductor chip 200 may be arranged apart from each other in the vertical direction Z by the first bump 250. A distance D1 between the first substrate 100 and the first semiconductor chip 200 in the vertical direction Z may be equal to or less than about 10 μm. The thickness of the first bump 250 in the vertical direction Z may be equal to or less than about 10 μm.

As the first substrate 100 and the first semiconductor chip 200 are apart from each other in the vertical direction Z by the first bump 250, a space may be formed between the first substrate 100 and the first semiconductor chip 200.

The first underfill layer 270 and the first molding member 390 may be arranged in a space between the first substrate 100 and the first semiconductor chip 200. According to some embodiments, each of the first underfill layer 270 and the first molding member 390 may include epoxy resin. Each of the first underfill layer 270 and the first molding member 390 may include fillers, the filler content of the first underfill layer 270 may be in a range of about 70% to about 95%, and the filler content of the first molding member 390 may be in a range of about 5% to about 40%. In this case, the filler content may be understood as a mass ratio.

According to some embodiments, the first underfill layer 270 may be arranged to overlap with the center portion of the first semiconductor chip 200 in the vertical direction Z. The first underfill layer 270 may be formed to fill a region corresponding to the center portion of the space between the first substrate 100 and the first semiconductor chip 200. In this case, the first underfill layer 270 may be formed only in the center portion of the space between the first substrate 100 and the first semiconductor chip 200 and may not be formed in a region corresponding to a periphery portion of the space between the first substrate 100 and the first semiconductor chip 200.

According to some embodiments, a volume occupied by the first underfill layer 270 among regions, except for a volume occupied by the first bump 250, in the space between the first substrate 100 and the first semiconductor chip 200 may be in a range of about 5% to about 50%. In some embodiments, the volume occupied by the first underfill layer 270 among regions, except for the volume occupied by the first bump 250, in the space between the first substrate 100 and the first semiconductor chip 200 may be in a range of about 10% to about 30%. When a ratio of the volume occupied by the first underfill layer 270 in a space between the first substrate 100 and the first semiconductor chip 200 is in a range of about 10% to about 30%, the first underfill layer 270 may fill a region, in which the first underfill layer 270 overlaps with the first semiconductor chip 200 in the vertical direction Z, in a space between the first substrate 100 and the first semiconductor chip 200, but may not fill a region in which the first underfill layer 270 does not overlap with the first semiconductor chip 200 in the vertical direction Z.

The first molding member 390 may be formed to cover the first semiconductor chip 200 and the conductive pillar 380. The first molding member 390 may cover both the upper surface and the side surfaces of the first semiconductor chip 200. In addition, the first molding member 390 may be formed in a space between the first substrate 100 and the first semiconductor chip 200. The first molding member 390 may be formed to fill a region corresponding to a periphery portion of the space between the first substrate 100 and the first semiconductor chip 200. In other words, the first molding member 390 may be formed to fill a region, except for a portion in which the first underfill layer 270 is formed, of the space between the first substrate 100 and the first semiconductor chip 200. The first molding member 390 arranged between the first substrate 100 and the first semiconductor chip 200 may not overlap with the center portion of the first semiconductor chip 200 in the vertical direction Z. The first molding member 390 formed between the first substrate 100 and the first semiconductor chip 200 may surround the first bump 250.

The plurality of first bumps 250 may be provided between the first substrate 100 and the first semiconductor chip 200, and while the first bumps 250 overlapping with the center portion of the first semiconductor chip 200 among the plurality of first bumps 250 may be surrounded by the first underfill layer 270, the first bumps 250 not overlapping the center portion of the first semiconductor chip 200 among the plurality of first bumps 250 may be surrounded by the first molding member 390 without being surrounded by the first underfill layer 270.

A volume occupied by the first molding member 390 in a space between the first substrate 100 and the first semiconductor chip 200 may be greater than the volume occupied by the first underfill layer 270. According to some embodiments, the volume occupied by the first molding member 390 among regions, except for the volume occupied by the first bump 250, in the space between the first substrate 100 and the first semiconductor chip 200 may be in a range of about 70% to about 90%. In the space between the first substrate 100 and the first semiconductor chip 200, two heterogeneous materials may be provided except for the first bump 250.

According to some embodiments, as illustrated in FIG. 1B, the first underfill layer 270 may be formed in the center portion of the space between the first substrate 100 and the first semiconductor chip 200. When the first underfill layer 270 is viewed in the vertical direction Z, at least a portion of the periphery region of the first underfill layer 270 may have a shape protruding toward the first molding member 390. However, the shape of the first underfill layer 270 viewed in the vertical direction Z is not limited thereto, and when the first underfill layer 270 is viewed in the vertical direction Z, the periphery region thereof may also have a circular or elliptical shape.

The conductive pillar 380 may be arranged apart from the first semiconductor chip 200 in a horizontal direction on the upper surface of the first substrate 100. The conductive pillar 380 may penetrate the first molding member 390 and extend in the vertical direction Z. The conductive pillar 380 may include, for example, a through mold via or a conductive post. The conductive pillar 380 may include, for example, Cu. According to some embodiments, the conductive pillar 380 may be provided in plural. In this case, a plurality of conductive pillars 380 may be arranged apart from each other in a horizontal direction.

The external connection terminal 160 may be arranged under the lower surface of the first substrate 100. The external connection terminal 160 may be electrically connected to an external connection device via a pad formed under the lower surface of the first substrate 100. The external connection device may include, for example, a motherboard PCB. According to some embodiments, the external connection terminal 160 may include a solder ball. In addition, in some embodiments, the external connection terminal 160 may also have a structure including a pillar and a solder. The external connection terminal 160 may include at least one from among Cu, silver (Ag), gold (Au), and tin (Sb).

The semiconductor package 10 according to an embodiment of the present disclosure may include the first underfill layer 270 and the first molding member 390 provided between the first substrate 100 and the first semiconductor chip 200. In this case, the first underfill layer 270 may be formed in a region corresponding to the center portion of the space between the first substrate 100 and the first semiconductor chip 200, and the first molding member 390 may be formed in the region corresponding to the periphery portion of the space between the first substrate 100 and the first semiconductor chip 200.

In a comparative embodiment, when the space between the first substrate 100 and the first semiconductor chip 200 is filled by the first molding member 390 during a molded underfill process, and when a distance D1 between the upper surface of the first substrate 100 and the lower surface of the first semiconductor chip 200 in the vertical direction Z is equal to or less than about 10 μm, there may be issues that the first molding member 390 is not formed uniformly and a void is formed between the first molding members 390. In addition, there has been a trend that a lot of voids are generated in a region corresponding to the center portion in the space between the first substrate 100 and the first semiconductor chip 200.

However, in the semiconductor package 10 according to an embodiment of the present disclosure, the first underfill layer 270 may be arranged in a region corresponding to the center portion, in which a lot of voids occur, in the space between the first substrate 100 and the first semiconductor chip 200 and the first molding member 390 may be arranged to surround the first underfill layer 270 to reduce the occurrence of the void. In other words, the first underfill layer 270 and the first molding member 390 may each be arranged in the space between the first substrate 100 and the first semiconductor chip 200 to reduce a defect in which the space between the first substrate 100 and the first semiconductor chip 200 is not fully filled.

In addition, by arranging the first underfill layer 270 only in a region, in which the void frequently occurs in the space between the first substrate 100 and the first semiconductor chip 200, and arranging the first molding member 390 including a material having greater properties (e.g., greater thermal conductivity and greater compression strength) than the first underfill layer 270 in the other region in the space between the first substrate 100 and the first semiconductor chip 200, the reliability of the semiconductor package 10 may be improved.

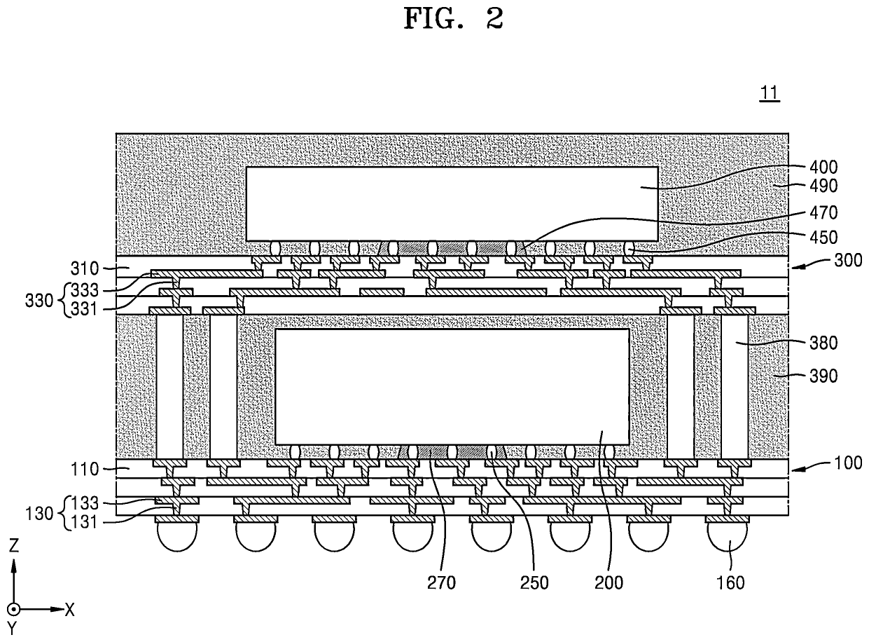

FIG. 2 is a schematic cross-sectional view of a semiconductor package 11 according to an embodiment. Hereinafter, duplicate descriptions of the semiconductor package 10 given with reference to FIG. 1 that apply to the semiconductor package 11 may be omitted, and differences thereof are mainly described.

Referring to FIG. 2, the semiconductor package 11 may include the first substrate 100, the first semiconductor chip 200, the conductive pillar 380, the first underfill layer 270, the first molding member 390, a second substrate 300, a second semiconductor chip 400, a second underfill layer 470, and a second molding member 490.

The first substrate 100 may be electrically connected to each of the first semiconductor chip 200, the conductive pillar 380, and an external connection terminal 160 and may include an insulating layer 110 surrounding a wiring 130 and an insulating layer 110 surrounding the wiring 130.

The first semiconductor chip 200 may be arranged on the upper surface of the first substrate 100. The first semiconductor chip 200 may be mounted on the upper surface of the first substrate 100 by using the first bump 250. The conductive pillar 380 may be arranged apart from the first semiconductor chip 200 in a horizontal direction on the upper surface of the first substrate 100. The conductive pillar 380 may include a vertical connection conductive material for electrically connecting the first substrate 100 to the second substrate 300.

The first underfill layer 270 may be arranged in the space between the first substrate 100 and the first semiconductor chip 200. The first underfill layer 270 may be arranged in a region corresponding to the center portion in the space between the first substrate 100 and the first semiconductor chip 200. The first underfill layer 270 may be formed to surround the first bump 250.

The first molding member 390 may be formed to surround the first semiconductor chip 200 and the conductive pillar 380 between the first substrate 100 and the second substrate 300. According to some embodiments, the first molding member 390 may be formed to fill a region corresponding to the periphery portion in the space between the first substrate 100 and the first semiconductor chip 200. According to some embodiments, the volume occupied by the first molding member 390 in a space between the first substrate 100 and the first semiconductor chip 200 may be greater than the volume occupied by the first underfill layer 270 between the first substrate 100 and the first semiconductor chip 200.

The second substrate 300 may be arranged on an upper surface of the first molding member 390, and may include a substrate on which the second semiconductor chip 400 is mounted. The second substrate 300 may be electrically connected to each of the conductive pillar 380 and the second semiconductor chip 400. The second substrate 300 may include a wiring 330 and at least one insulating layer 310 surrounding the wiring 330.

The wiring 330 may include a line pattern 333 and a via pattern 331. The line pattern 333 may have a shape extending in the horizontal direction along at least one from among an upper surface and a lower surface of each of the at least one insulating layer 310 stacked in the vertical direction Z. The via pattern 331 may have a shape extending and penetrating the insulating layer 310 in the vertical direction Z. The via pattern 331 may electrically connect together the line patterns 333 at different vertical levels. In some embodiments, at least a portion of the line patterns 333 may be formed together with a portion of the via patterns 331 into one body.

In some embodiments, the second substrate 300 may include a ceramic substrate, a PCB, or an organic substrate. In addition, in some embodiments, the second substrate 300 may include a rewiring structure formed by using a rewiring process.

The second semiconductor chip 400 may be arranged on the upper surface of the second substrate 300. According to some embodiments, the second semiconductor chip 400 may include at least one from among a memory chip and a logic chip.

The second semiconductor chip 400 may be mounted on the second substrate 300 by using a second bump 450 in a flip chip manner. The second semiconductor chip 400 may be electrically connected to the second substrate 300 via the second bump 450. The second bump 450 may be electrically connected to the second substrate 300 and the second semiconductor chip 400 by physical contact with both a pad formed on the upper surface of the second substrate 300 and a pad formed under the lower surface of the second semiconductor chip 400.

The second substrate 300 and the second semiconductor chip 400 may be apart from each other in the vertical direction Z by the second bump 450. As the second substrate 300 and the second semiconductor chip 400 are apart from each other in the vertical direction Z by the second bump 450, a space may be formed between the second substrate 300 and the second semiconductor chip 400.

The second underfill layer 470 and the second molding member 490 may be arranged in the space between the second substrate 300 and the second semiconductor chip 400. According to some embodiments, the second underfill layer 470 and the second molding member 490 may each include epoxy resin. Each of the second underfill layer 470 and the second molding member 490 may include fillers, the filler content of the second underfill layer 470 may be in a range of about 70% to about 95%, and the filler content of the second molding member 490 may be in a range of about 5% to about 40%. In this case, the filler content may be understood as a mass ratio.

According to some embodiments, the second underfill layer 470 may be arranged to overlap with the center portion of the second semiconductor chip 400 in the vertical direction Z. The second underfill layer 470 may be formed to fill a region corresponding to the center portion of the space between the second substrate 300 and the second semiconductor chip 400. In this case, the second underfill layer 470 may be formed only in the center portion of the space between the second substrate 300 and the second semiconductor chip 400, and may not be formed in a region corresponding to a periphery portion of the space between the second substrate 300 and the second semiconductor chip 400.

According to some embodiments, a volume occupied by the second underfill layer 470 among regions, except for a volume occupied by the second bump 450, in the space between the second substrate 300 and the second semiconductor chip 400 may be in a range of about 5% to about 50%.

The second molding member 490 may be formed on the upper surface of the second substrate 300, and may be formed to cover the second semiconductor chip 400. The second molding member 490 may cover both the upper surface and the side surfaces of the second semiconductor chip 400. In addition, the second molding member 490 may be formed in the space between the second substrate 300 and the second semiconductor chip 400. The second molding member 490 may be formed to fill a region corresponding to a periphery portion of the space between the second substrate 300 and the second semiconductor chip 400. In other words, the second molding member 490 may be formed to fill a region, except for a portion in which the second underfill layer 470 is formed, of the space between the second substrate 300 and the second semiconductor chip 400. The second molding member 490 arranged between the second substrate 300 and the second semiconductor chip 400 may not overlap with the center portion of the second semiconductor chip 400 in the vertical direction Z. The second molding member 490 formed between the second substrate 300 and the second semiconductor chip 400 may surround the second bump 450.

A plurality of the second bumps 450 may be provided between the second substrate 300 and the second semiconductor chip 400, and while second bumps 450 overlapping with the center portion of the second semiconductor chip 400 among the plurality of second bumps 450 may be surrounded by the second underfill layer 470, the second bumps 450 not overlapping the center portion of the second semiconductor chip 400 among the plurality of second bumps 450 may be surrounded by the second molding member 490.

A volume occupied by the second molding member 490 in a space between the second substrate 300 and the second semiconductor chip 400 may be greater than the volume occupied by the second underfill layer 470. According to some embodiments, the volume occupied by the second molding member 490 among regions, except for the volume occupied by the second bump 450, in the space between the second substrate 300 and the second semiconductor chip 400 may be in a range of about 70% to about 90%. In the space between the second substrate 300 and the second semiconductor chip 400, two heterogeneous materials may be provided except for the second bump 450.

When the second underfill layer 470 is viewed in the vertical direction Z, a portion of the periphery region of the second underfill layer 470 may have a shape protruding toward the second molding member 490. However, the shape of the second underfill layer 470 viewed in the vertical direction Z is not limited thereto, and when the second underfill layer 470 is viewed in the vertical direction Z, the periphery region thereof may also have a circular or elliptical shape.

The semiconductor package 11 according to an embodiment of the present disclosure may include the first underfill layer 270 and the first molding member 390 provided between the first substrate 100 and the first semiconductor chip 200, and include the second underfill layer 470 and the second molding member 490 provided between the second substrate 300 and the second semiconductor chip 400. Accordingly, voids generated inside the semiconductor package 11 may be reduced and the reliability of the semiconductor package 11 may be improved.

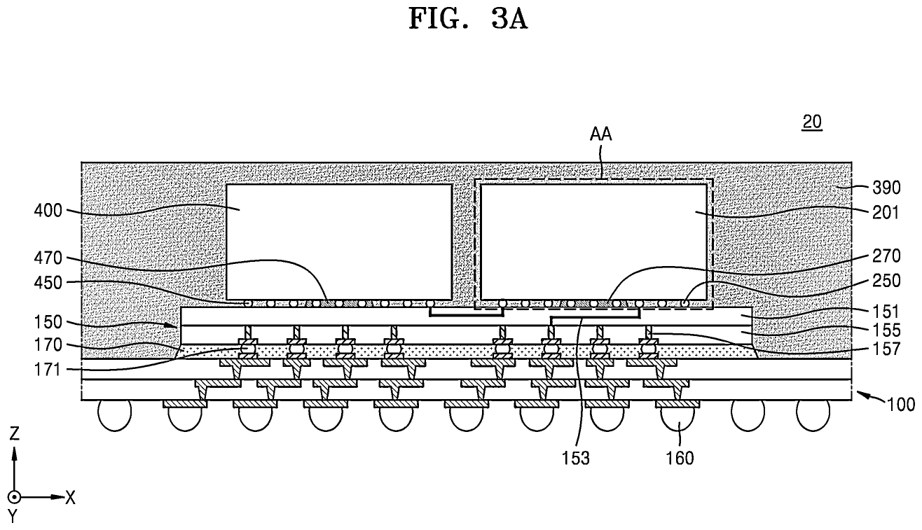

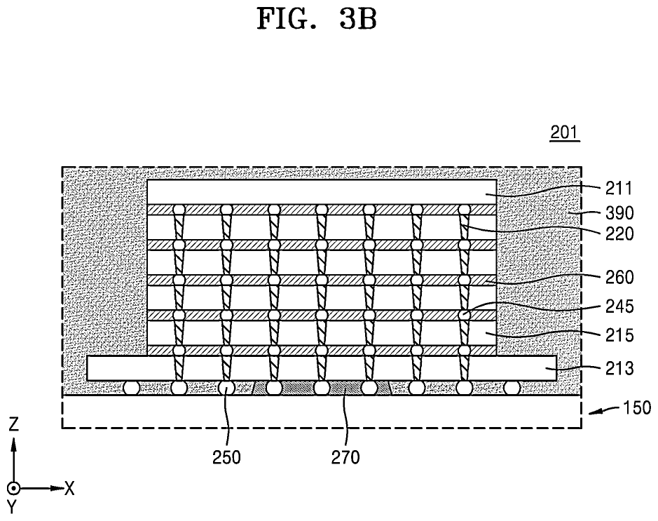

FIG. 3A is a schematic cross-sectional view of a semiconductor package 20 according to an embodiment. FIG. 3B is an enlarged diagram of region AA in FIG. 3A. Hereinafter, duplicate descriptions of the semiconductor package 10 of FIG. 1 and the semiconductor package 20 of FIGS. 3A and 3B may be omitted and differences therebetween are mainly described.

Referring to FIGS. 3A and 3B, the semiconductor package 20 may include the first substrate 100, an interposer substrate 150, a first semiconductor chip 201, the second semiconductor chip 400, an underfill material layer 170, the first underfill layer 270, the second underfill layer 470, and the first molding member 390.

Because the first substrate 100 is substantially the same as or similar to the first substrate 100 described with reference to FIG. 1, repeated descriptions thereof may be omitted.

The interposer substrate 150 may be arranged on the upper surface of the first substrate 100. The interposer substrate 150 may be formed of silicon, and may electrically connect the first semiconductor chip 201 to the second semiconductor chip 400. According to some embodiments, the interposer substrate 150 may be electrically connected to the first substrate 100 via a bump 171. The underfill material layer 170 surrounding the bump 171 may be arranged between the first substrate 100 and the interposer substrate 150. The underfill material layer 170 may include, for example, epoxy resin formed by using a capillary underfill method. However, in some embodiments, the first molding member 390 may also directly fill a space between the first substrate 100 and the interposer substrate 150 by using a molded underfill process. In this case, the underfill material layer 170 may be omitted.

The interposer substrate 150 may include a wiring layer 151 and a body layer 155. The wiring layer 151 may be arranged on an upper surface of the body layer 155. The wiring layer 151 may include a wiring pattern 153. The wiring pattern 153 may electrically connect the first semiconductor chip 201 to the second semiconductor chip 400, or may electrically connect together the first semiconductor chip 201 and one or more of the through electrode 157, and electrically connect together the second semiconductor chip 400 and one or more of the through electrode 157.

The through electrode 157 may be formed inside the body layer 155. The through electrode 157 may penetrate the body layer 155 in the vertical direction Z. According to some embodiments, the through electrode 157 may include a silicon through silicon via (TSV). The through electrode 157 may be electrically connected to the bump 171 via a pad formed under a lower surface of the body layer 155.

Each of the first semiconductor chip 201 and the second semiconductor chip 400 may be arranged on the upper surface of the interposer substrate 150. The first semiconductor chip 201 may be mounted on the upper surface of the interposer substrate 150 via the first bump 250, and the second semiconductor chip 400 may be mounted on the upper surface of the interposer substrate 150 via the second bump 450.

The first underfill layer 270 and the first molding member 390 may be arranged between the interposer substrate 150 and the first semiconductor chip 201, and the second underfill layer 470 and the first molding member 390 may be arranged between the interposer substrate 150 and the second semiconductor chip 400.

The first underfill layer 270 may be arranged to overlap with the center portion of the first semiconductor chip 201 in the vertical direction Z. The first underfill layer 270 may be formed to fill a region corresponding to the center portion of the space between the interposer substrate 150 and the first semiconductor chip 201. In this case, the first underfill layer 270 may be formed only in the center portion of the space between the interposer substrate 150 and the first semiconductor chip 201, and may not be formed in a region corresponding to a periphery portion of the space between the interposer substrate 150 and the first semiconductor chip 201.

The second underfill layer 470 may be arranged to overlap with the center portion of the second semiconductor chip 400 in the vertical direction Z. The second underfill layer 470 may be formed to fill a region corresponding to the center portion of the space between the interposer substrate 150 and the second semiconductor chip 400. In this case, the second underfill layer 470 may be formed only in the center portion of the space between the interposer substrate 150 and the second semiconductor chip 400, and may not be formed in a region corresponding to a periphery portion of the space between the interposer substrate 150 and the second semiconductor chip 400.

The first molding member 390 may cover the first semiconductor chip 201. the second semiconductor chip 400, and the interposer substrate 150. The first molding member 390 may fill a space between the interposer substrate 150 and the first semiconductor chip 201, and a space between the interposer substrate 150 and the second semiconductor chip 400. The first molding member 390 may be formed to fill a region corresponding to the periphery portion of each of the space between the interposer substrate 150 and the first semiconductor chip 201 and a space between the interposer substrate 150 and the second semiconductor chip 400. In other words, the first molding member 390 may be formed to fill a region, except for a portion in which the first underfill layer 270 is formed, in the space between the interposer substrate 150 and the first semiconductor chip 201, and to fill a region, except for a portion in which the second underfill layer 470 is formed, in the space between the interposer substrate 150 and the second semiconductor chip 400. The first molding member 390 arranged between the interposer substrate 150 and the first semiconductor chip 201 may not overlap with the center portion of the first semiconductor chip 201 in the vertical direction Z, and the first molding member 390 arranged between the interposer substrate 150 and the second semiconductor chip 400 may not overlap with the center portion of the second semiconductor chip 400 in the vertical direction Z.

According to some embodiments, in the space between the interposer substrate 150 and the first semiconductor chip 201, a volume occupied by the first molding member 390 may be greater than a volume occupied by the first underfill layer 270. In addition, in a space between the interposer substrate 150 and the second semiconductor chip 400, a volume occupied by the first molding member 390 may be greater than the volume occupied by the second underfill layer 470.

According to some embodiments, the first semiconductor chip 201 may include a plurality of semiconductor chips stacked in the vertical direction Z. In this case, the first semiconductor chip 201 may be understood as a chip stack structure. Semiconductor chips included in the first semiconductor chip 201 may, as high bandwidth memory (HBM) DRAM chips, include semiconductor chips used in an HBM package. According to some embodiments, with reference to FIG. 3B, the first semiconductor chip 201 may include a base chip 213 and at least one HBM chips 215 stacked on the base chip 213 in the vertical direction Z. The base chip 213 may be a lowermost portion of the first semiconductor chip 201. Each of the base chip 213 and the HBM chips 215 may include at least one through electrode 220 therein. On the other hand, a top layer HBM chip 211, that is an uppermost one among the HBM chips 215, may not include the through electrode 220.

According to some embodiments, the base chip 213 may include logic devices. Accordingly, the base chip 213 may include a logic chip. The base chip 213 may be arranged under the HBM chips 215, combine signals of the HBM chips 215 to transfer to the outside, and in addition, may transfer signals and power from the outside to the HBM chips 215. Accordingly, the base chip 213 may be referred to as a buffer chip or a control chip. The HBM chip 215 may be referred to as a memory chip or a core chip.

The HBM chips 215 may be stacked on the base chip 213 by using a pad-to-pad bonding, a bonding using a bonding member, or a bonding using an anisotropic conductive film (ACF). According to some embodiments, the HBM chips 215 may be stacked by using at least one third bump 245 in a flip chip method. The third bump 245 may include a micro bump. An underfill material layer 260 may be formed between the base chip 213 and the lowermost one among HBM chips 215, and between the HBM chips 215. The underfill material layer 260 may fix the third bump 245, the base chip 213, and the HBM chips 215.

The at least one through electrode 220 formed in the base chip 213 and the HBM chips 215 may also be electrically connected to the at least one third bump 245. The through electrode 220 may extend in the vertical direction Z. The through electrode 220 may have a tapered shape in which a horizontal width of the through electrode 220 decreases as a vertical level decreases.

In the semiconductor package 20 according to an embodiment of the present disclosure, the first underfill layer 270 and the first molding member 390 may be arranged in a space between the interposer substrate 150 and the first semiconductor chip 201, and the second underfill layer 470 and the second molding member 490 may be arranged in a space between the interposer substrate 150 and the second semiconductor chip 400. Accordingly, a void generated in the semiconductor package 20 may be reduced and the reliability of the semiconductor package 20 may be improved.

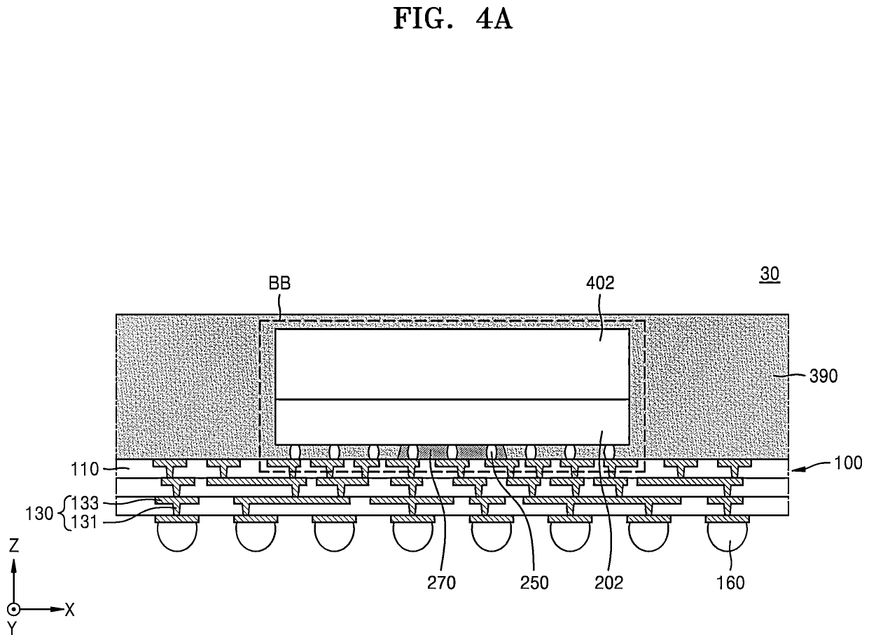

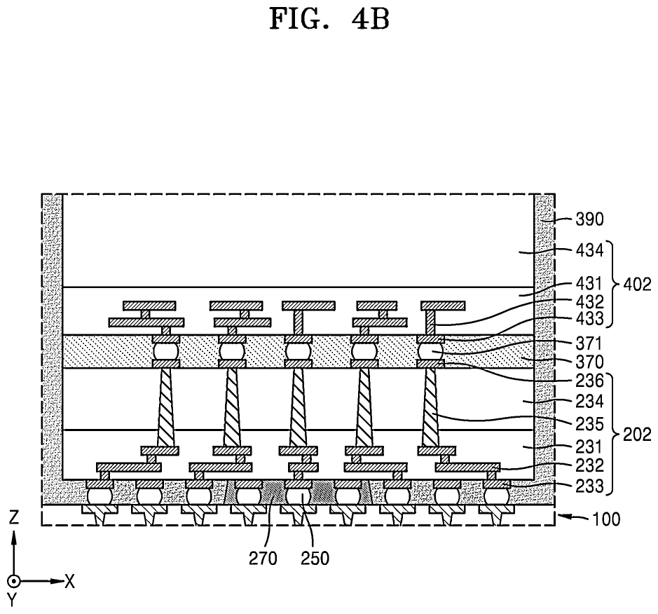

FIG. 4A is a schematic cross-sectional view of a semiconductor package 30 according to an embodiment. FIG. 4B is an enlarged diagram of region BB in FIG. 4A.

Hereinafter, duplicate descriptions of the semiconductor package 10 given with reference to FIG. 1 that apply to the semiconductor package 30 may be omitted, and differences thereof are mainly described.

Referring to FIGS. 4A and 4B, the semiconductor package 30 may include the first substrate 100, a first semiconductor chip 202, a second semiconductor chip 402, the first underfill layer 270, and the first molding member 390.

Because the first substrate 100 is substantially the same as or similar to the first substrate 100 described with reference to FIG. 1, repeated descriptions thereof may be omitted.

The first semiconductor chip 202 may be arranged on the upper surface of the first substrate 100 by using the first bump 250. The first underfill layer 270 and the first molding member 390 may be arranged in a space between the first substrate 100 and the first semiconductor chip 202. The first underfill layer 270 may be arranged to overlap with the center portion of the first semiconductor chip 202 in the vertical direction Z.

The first underfill layer 270 may be formed to fill a region corresponding to the center portion of the space between the first substrate 100 and the first semiconductor chip 202. In this case, the first underfill layer 270 may be formed only in the center portion of the space between the first substrate 100 and the first semiconductor chip 202, and may not be formed in a region corresponding to a periphery portion of the space between the first substrate 100 and the first semiconductor chip 202.

The first molding member 390 may be formed to cover the first semiconductor chip 202 and the second semiconductor chip 402. In this case, the first molding member 390 may be formed in a space between the first substrate 100 and the first semiconductor chip 202. The first molding member 390 may be formed to fill a region corresponding to a periphery portion of the space between the first substrate 100 and the first semiconductor chip 202. In other words, the first molding member 390 may be formed to fill a region, except for a portion in which the first underfill layer 270 is formed, of the space between the first substrate 100 and the first semiconductor chip 202. The first molding member 390 arranged between the first substrate 100 and the first semiconductor chip 202 may not overlap with the center portion of the first semiconductor chip 202 in the vertical direction Z. The first molding member 390 formed between the first substrate 100 and the first semiconductor chip 202 may surround the first bump 250.

The second semiconductor chip 402 may be mounted on an upper surface of the first semiconductor chip 202. The second semiconductor chip 402 may be electrically connected to the first semiconductor chip 202. According to some embodiments, each of the first semiconductor chip 202 and the second semiconductor chip 402 may include a logic chip and a memory chip. For example, both the first semiconductor chip 202 and the second semiconductor chip 402 may include memory chips of the same type, or one of the first semiconductor chip 202 and the second semiconductor chip 402 may include a memory chip and the other thereof may include a logic chip. In some embodiments, at least one from among the first semiconductor chip 202 and the second semiconductor chip 402 may have a chiplet structure including a plurality of chiplets.

An adhesive layer 370 may be configured to adhere the first semiconductor chip 202 to the second semiconductor chip 402. The adhesive layer 370 may be arranged between the first semiconductor chip 202 to the second semiconductor chip 402. According to some embodiments, the adhesive layer 370 may include an non-conductive film (NCF) and a die attach film (DAF).

The first semiconductor chip 202 may include a first semiconductor substrate 234, a first semiconductor device layer 231, at least one first bump pad 233, and at least one second bump pad 236.

The first semiconductor substrate 234 may include an upper surface and a lower surface opposite to each other. The upper surface may be a surface facing the second semiconductor chip 402, and the lower surface may be a surface facing the first substrate 100. The upper surface may be referred to as an inactive surface, and the lower surface may be referred to as an active surface.

The first semiconductor substrate 234 may include silicon (Si), for example, crystalline silicon, polycrystalline silicon, or amorphous silicon. Alternatively, the first semiconductor substrate 234 may include a semiconductor element such as germanium (Ge), or a compound semiconductor, such as silicon carbide (SiC), gallium arsenide (GaAs), indium arsenide (InAs), and indium phosphide (InP). On the other hand, the first semiconductor substrate 234 may have a silicon on insulator (SOI) structure. For example, the first semiconductor substrate 234 may include a buried oxide (BOX) layer. The first semiconductor substrate 234 may include a conductive region, for example, a well doped with impurities or a structure doped with impurities. In addition, the first semiconductor substrate 234 may have various device isolation structures such as a shallow trench isolation (STI) structure.

The first semiconductor device layer 231 may include a first wiring pattern 232 electrically connected to a plurality of semiconductor devices formed on the first semiconductor substrate 234. The first wiring pattern 232 may include a metal wiring layer and a via plug. For example, the first wiring pattern 232 may have a multi-layer structure in which two or more metal wiring layers or two or more via plugs are alternately stacked.

According to some embodiments, the first semiconductor device layer 231 may be formed under the lower surface (e.g., the active surface) of the first semiconductor substrate 234. According to some embodiments, the first semiconductor device layer 231 may be formed under the first semiconductor substrate 234. The first semiconductor substrate 234 may be apart from the first substrate 100 with the first semiconductor device layer 231 therebetween. The first semiconductor chip 202 may include at least one through electrode 235 penetrating a portion of the first semiconductor device layer 231 and the first semiconductor substrate 234.

The first bump pad 233 may be arranged under a lower surface of the first semiconductor device layer 231, and may be electrically connected to the first wiring pattern 232 inside the first semiconductor device layer 231. The first bump pad 233 may be electrically connected to the through electrode 235 via the first wiring pattern 232.

The through electrode 235 may penetrate the first semiconductor substrate 234 and a portion of the first semiconductor device layer 231. The through electrode 235 may extend from the first semiconductor device layer 231 toward the upper surface of the first semiconductor substrate 234 in the vertical direction Z, and may be electrically connected to the first wiring pattern 232 provided in the first semiconductor device layer 231. Accordingly, the first bump pad 233 may be electrically connected to the through electrode 235 via the first wiring pattern 232. The through electrode 235 may have a tapered shape in which a horizontal direction width of the through electrode 235 decreases or increases as a level of the through electrode 235 in the vertical direction Z increases. At least a portion of the through electrode 235 may have a pillar shape. The through electrode 235 may include a silicon through electrode.

The second bump pad 236 may be formed on the upper surface of the first semiconductor substrate 234, that is, on the inactive surface of the first semiconductor substrate 234. The second bump pad 236 may include substantially the same material as a material of the first bump pad 233. In addition, according to some embodiments, a passivation layer may be formed to surround a portion of side surfaces of the second bump pad 236 on the upper surface of the first semiconductor substrate 234.

The first bump 250 may be arranged to be in contact with the first bump pad 233. The first semiconductor chip 202 may receive from the outside at least one from among a control signal, a power signal, and a ground signal for an operation of the first semiconductor chip 202 via the first bump 250, receive from the outside a data signal to be stored in the first semiconductor chip 202, or may provide to the outside data stored in the first semiconductor chip 202.

The second semiconductor chip 402 may include a second semiconductor substrate 434, a second semiconductor device layer 431, and at least one third bump pad 433. Because the second semiconductor chip 402 is the same as or has similar characteristics to the first semiconductor chip 202, the differences from the first semiconductor chip 202 are mainly described.

The second semiconductor substrate 434 may include a lower surface and an upper surface opposite to each other. The lower surface of the second semiconductor substrate 434 may face the first semiconductor chip 202, and the upper surface thereof may be opposite to the lower surface. The upper surface of the second semiconductor substrate 434 may be referred to as an inactive surface, and the lower surface of the second semiconductor substrate 434 may be referred to as an active surface.

The second semiconductor device layer 431 may include a second wiring pattern 432 electrically connected to the plurality of semiconductor devices formed on the second semiconductor substrate 434. The second wiring pattern 432 may include a metal wiring layer and a via plug. For example, the second wiring pattern 432 may have a multi-layer structure in which two or more metal wiring layers or two or more via plugs are alternately stacked.

According to some embodiments. the second semiconductor device layer 431 may be formed on a lower surface (e.g., an active surface) of the second semiconductor substrate 434. The second semiconductor device layer 431 may be under the second semiconductor substrate 434. The second semiconductor substrate 434 may be apart from the first semiconductor chip 202 in the vertical direction Z with the second semiconductor device layer 431 therebetween.

The third bump pad 433 may be arranged under the lower surface of the second semiconductor device layer 431, and may be electrically connected to the second wiring pattern 432 in the second semiconductor device layer 431.

The adhesive layer 370 may be arranged between the first semiconductor chip 202 to the second semiconductor chip 402. The adhesive layer 370 may fix the second semiconductor chip 402 onto the first semiconductor chip 202.

At least one fourth bump 371 may be arranged to be in contact with the at least one second bump pad 236 and the at least one third bump pad 433. The fourth bump 371 may be electrically connected to the first semiconductor chip 202 and the second semiconductor chip 402. The second semiconductor chip 402 may be electrically connected to the first semiconductor chip 202 via the fourth bump 371 arranged between the first semiconductor chip 202 and the second semiconductor chip 402. The second semiconductor chip 402 may receive, from the outside, at least one from among a control signal, a power signal, and a ground signal for an operation of the second semiconductor chip 402 via the fourth bump 371, receive a data signal to be stored in the second semiconductor chip 402, or may provide to the outside data stored in the second semiconductor chip 402.

Because, in the semiconductor package 30 according to an embodiment of the present disclosure, the first underfill layer 270 and the first molding member 390 are arranged between the first substrate 100 and the first semiconductor chip 202, a void generated in the semiconductor package 30 may be reduced and the reliability of the semiconductor package 30 may be improved.

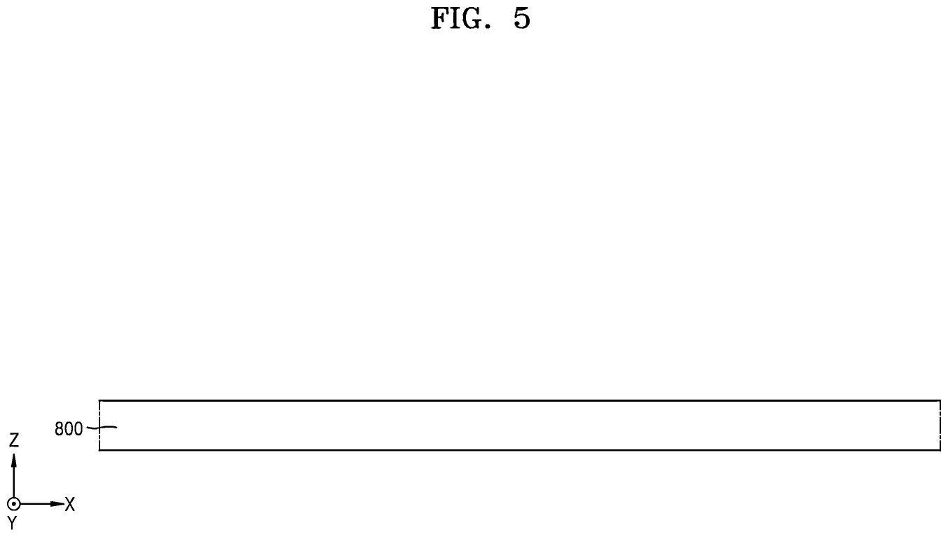

FIGS. 5 through 12 are schematic cross-sectional views illustrating a method of manufacturing a semiconductor package, according to embodiments. Hereinafter, duplicate descriptions of the semiconductor package 10 given with reference to FIG. 1 may be omitted, and the differences thereof are mainly described.

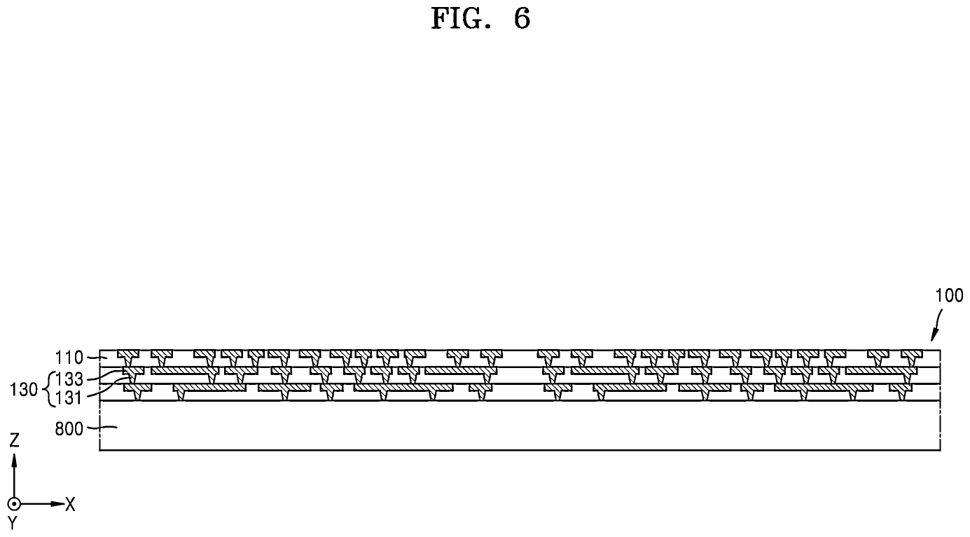

Referring to FIGS. 5 and 6, the first substrate 100 may be arranged on a carrier substrate 800. Because the first substrate 100 is substantially the same as or similar to the first substrate 100 described with reference to FIG. 1, repeated descriptions thereof may be omitted. According to some embodiments, the first substrate 100 may be formed on the carrier substrate 800 without a gap. In other words, a footprint of the first substrate 100 may be substantially the same as a footprint of the carrier substrate 800.

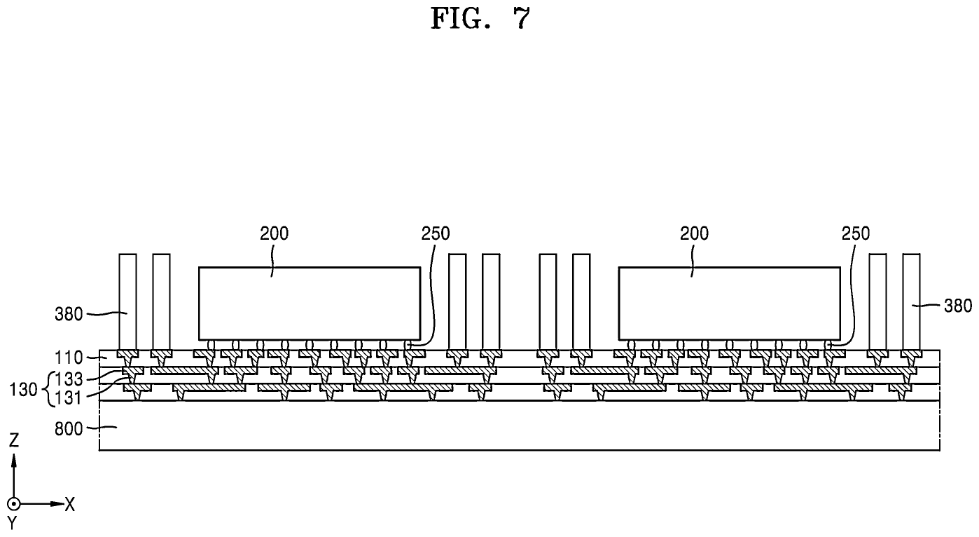

Referring to FIG. 7, at least one first semiconductor chip 200 and at least one conductive pillar 380 may be arranged on the first substrate 100. On the first substrate 100, a plurality of first semiconductor chips 200 and the conductive pillars 380 may be arranged. According to some embodiments, the conductive pillar 380 may be formed by filling copper or the like into a photoresist opening, which is formed by using a photoresist doping process, an exposure process, and an etching process. The first semiconductor chip 200 may be mounted on the first substrate 100 by using at least one first bump 250 in a flip chip manner.

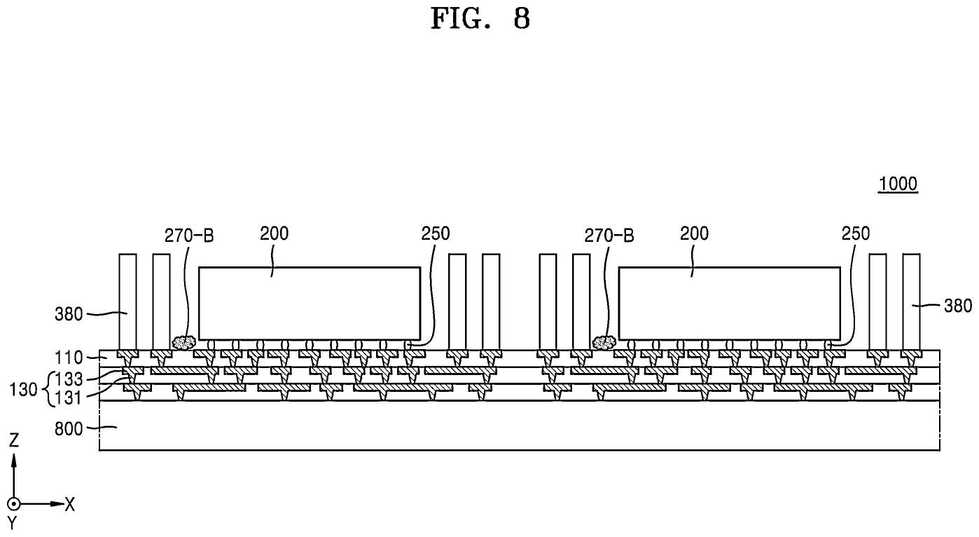

Referring to FIG. 8, a first structure 1000 may be formed by discharging at least one first underfill ball 270-B on the first substrate 100. The first underfill ball 270-B may include a material (e.g., epoxy resin including a filler) in a state before being cured. The first underfill ball 270-B may be discharged onto the upper surface of the first substrate 100, and may not be in contact with the conductive pillar 380. According to some embodiments, the first underfill ball 270-B may be between the first semiconductor chip 200 and the conductive pillar 380. In some embodiments, at least a portion of the first underfill ball 270-B may overlap with the first semiconductor chip 200 in the vertical direction Z. In other words, at least a portion of the first underfill ball 270-B may be between the first substrate 100 and the first semiconductor chip 200.

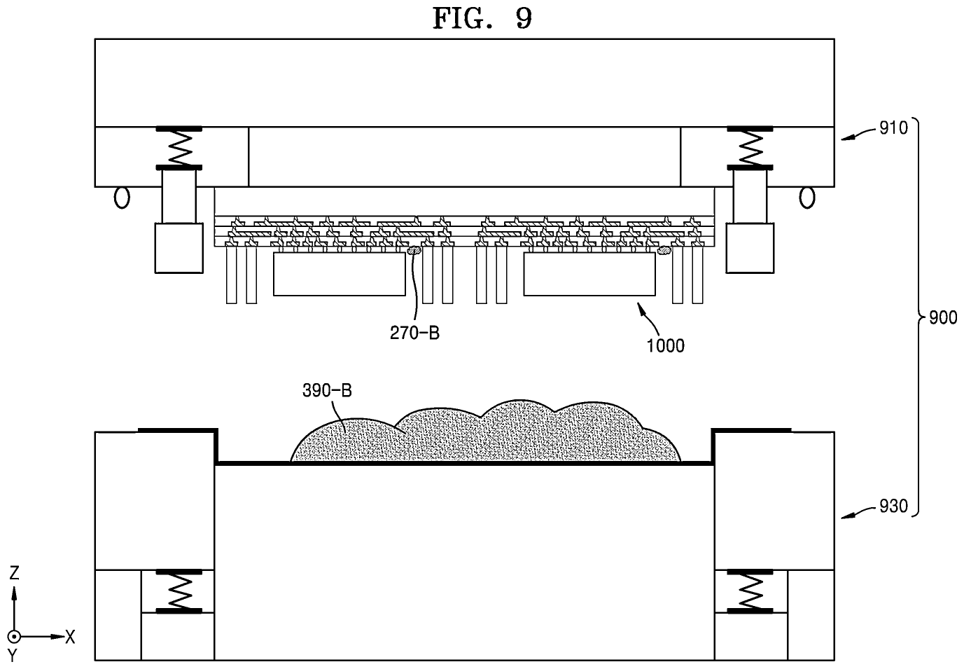

Referring to FIG. 9, the first structure 1000 of FIG. 8 may be provided in a molding device 900. The molding device 900 may include an upper portion mold 910 and a lower portion mold 930. According to some embodiments, the first structure 1000 may be provided to the upper portion mold 910, and may be provided in a state in which the first structure 1000 is overturned in the vertical direction Z. A first molding ball 390-B may be provided on the lower portion mold 930. The first molding ball 390-B may include a material (e.g., epoxy resin including a filler) in a state before being cured.

The upper portion mold 910 and the lower portion mold 930 may be provided in an open state. In other words, the upper portion mold 910 and the lower portion mold 930 may be provided in a state in which they are apart from each other in the vertical direction Z. An empty space may be formed between the upper portion mold 910 and the lower portion mold 930. According to some embodiments, at least one of the upper portion mold 910 and the lower portion mold 930 may be moved in the vertical direction Z.

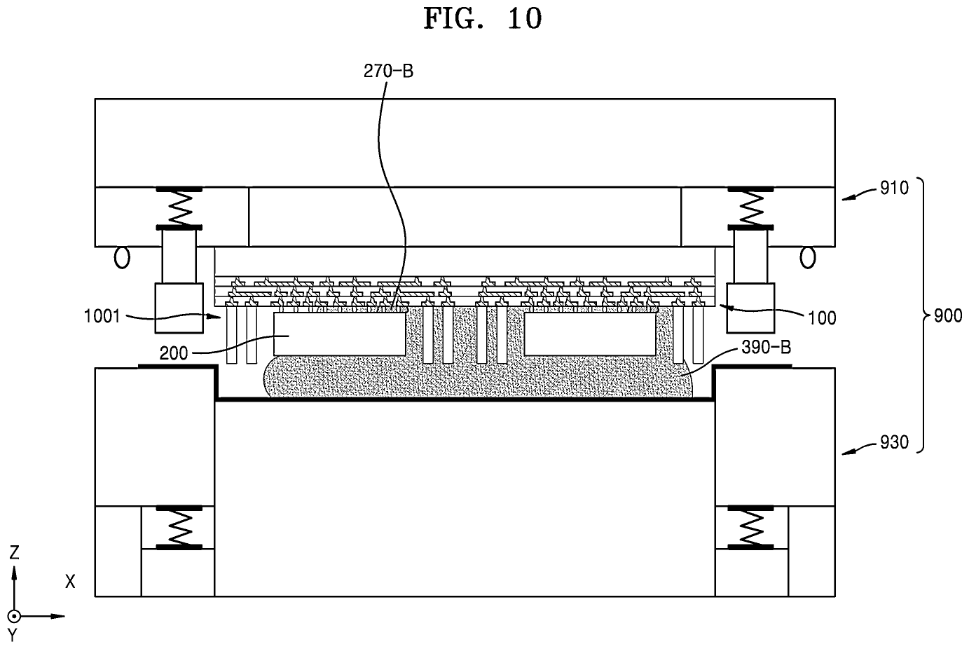

Referring to FIG. 10, a first structure 1001 may be formed by closing a portion of the molding device 900 and contacting the first molding ball 390-B with the first structure 1000 of FIG. 9.

The first molding ball 390-B may partially cover the first structure 1001. In addition, the first underfill ball 270-B formed adjacent to the first semiconductor chip 200 may be moved into the space between the first substrate 100 and the first semiconductor chip 200 due to pressure applied to the first structure 1001. In other words, the first underfill ball 270-B may be moved to the center of the first semiconductor chip 200.

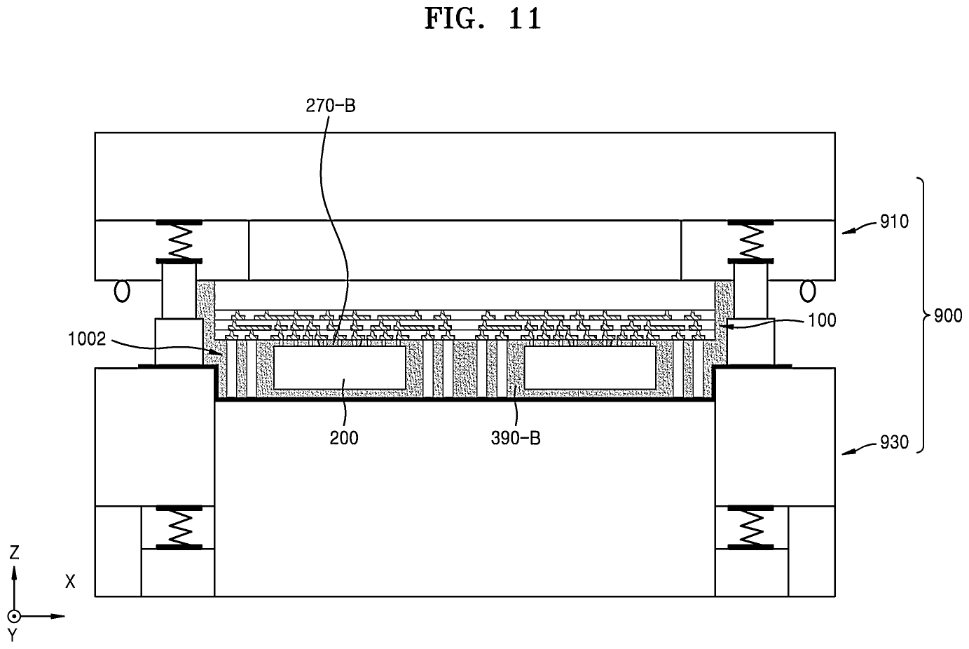

Referring to FIG. 11, the molding device 900 may be completely closed and the first molding ball 390-B may completely cover the first structure 1001, to form a first structure 1002. The first molding ball 390-B may completely cover the first structure 1002. In addition, the first underfill ball 270-B may be moved to a region, where the first underfill ball 270-B overlaps with the center portion of the first semiconductor chip 200 in the vertical direction Z, due to pressure applied to the first structure 1001. In other words, the first underfill ball 270-B may be moved to a region corresponding to the center portion of the space between the first substrate 100 and the first semiconductor chip 200.

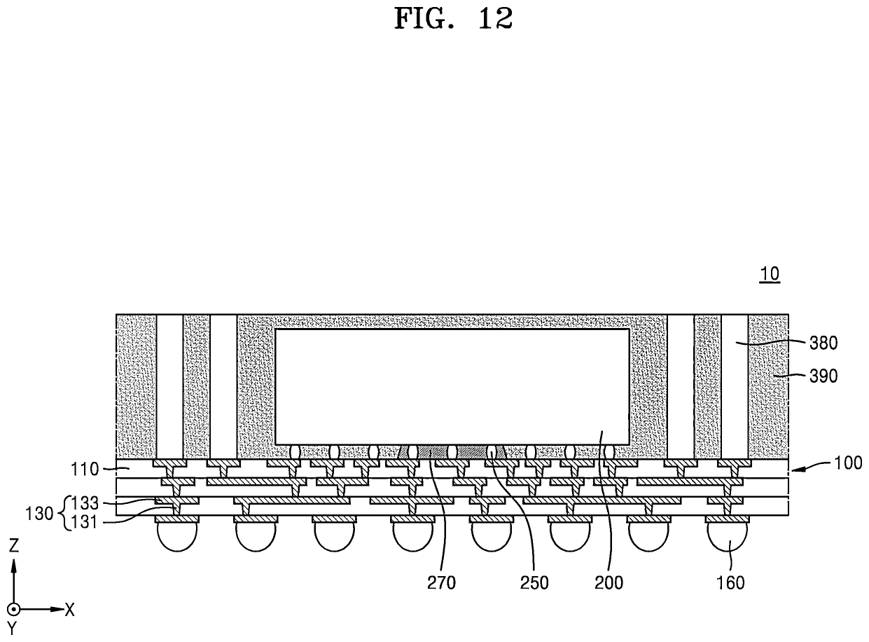

Referring to FIG. 12, after the first structure 1002 in FIG. 11 is removed from the molding device 900, by curing the first underfill ball 270-B of the first structure 1002 and the first molding ball 390-B and performing a grinding process, the semiconductor package 10 may be provided.

While non-limiting example embodiments of present disclosure have been particularly shown and described, it will be understood that various changes in form and details may be made therein without departing from the spirit and scope of the present disclosure.

1. A semiconductor package comprising:
a first substrate;
a first semiconductor chip on an upper surface of the first substrate;
at least one first bump between the first substrate and the first semiconductor chip, the at least one first bump being configured to electrically connect the first substrate to the first semiconductor chip;
a first underfill layer that fills a center portion of a space between the first substrate and the first semiconductor chip; and
a first molding member that covers an upper surface and side surfaces of the first semiconductor chip, and fills a periphery portion of the space between the first substrate and the first semiconductor chip,
wherein a volume occupied by the first molding member in the space between the first substrate and the first semiconductor chip is greater than a volume occupied by the first underfill layer in the space between the first substrate and the first semiconductor chip.

2. The semiconductor package of claim 1, wherein a distance between the upper surface of the first substrate and a lower surface of the first semiconductor chip in a vertical direction is less than 10 μm.

3. The semiconductor package of claim 1, wherein
the at least one first bump comprises a plurality of micro bumps,
wherein a threshold dimension of each of the plurality of micro bumps is less than 20 μm, and
wherein a distance from a center of one of the plurality of micro bumps to a center of another of the plurality of micro bumps, directly adjacent to the one of the plurality of micro bumps, is less than 50 μm.

4. The semiconductor package of claim 1, wherein
each of the first molding member and the first underfill layer comprises a filler,
wherein a filler content of the first molding member is in a range of 70% to 90%, and
wherein a filler content of the first underfill layer is in a range of 5% to 40%.

5. The semiconductor package of claim 1, wherein
the first underfill layer overlaps with a center portion of the first semiconductor chip in a vertical direction, and
wherein the first molding member surrounds the first underfill layer.

6. The semiconductor package of claim 1, further comprising:
a conductive pillar on the upper surface of the first substrate and spaced apart from the first semiconductor chip in a horizontal direction;
a second substrate on an upper surface of the first molding member;
a second semiconductor chip on an upper surface of the second substrate;
at least one second bump between the second substrate and the second semiconductor chip;
a second underfill layer that fills a center portion of a space between the second substrate and the second semiconductor chip; and
a second molding member that fills a periphery portion of the space between the second substrate and the second semiconductor chip.

7. The semiconductor package of claim 1, wherein at least a portion of a periphery region of the first underfill layer comprises a shape that, when the first underfill layer is viewed in a vertical direction, protrudes toward the first molding member.

8. The semiconductor package of claim 1, further comprising:
a second semiconductor chip;
an interposer substrate on the upper surface of the first substrate, wherein the first semiconductor chip and the second semiconductor chip are on an upper surface of the interposer substrate; and
a second underfill layer and a second molding member between the interposer substrate and the second semiconductor chip;
wherein the first underfill layer and the first molding member are between the interposer substrate and the first semiconductor chip, and
wherein the first underfill layer overlaps with a center portion of the first semiconductor chip in a vertical direction, and the second underfill layer overlaps with a center portion of the second semiconductor chip in the vertical direction.

9. The semiconductor package of claim 1, further comprising a second semiconductor chip on an upper portion of the first semiconductor chip,
wherein the first semiconductor chip comprises a first semiconductor substrate and a through electrode that penetrates the first semiconductor substrate in a vertical direction.

10. The semiconductor package of claim 1, wherein the volume occupied by the first underfill layer in the space between the first substrate and the first semiconductor chip is in a range of 5% to 50% of the space, excluding a volume of the space occupied by the at least one first bump.

11. A semiconductor package comprising:
a first substrate;
a first semiconductor chip on an upper surface of the first substrate;
at least one first bump between the first substrate and the first semiconductor chip, and configured to electrically connect the first substrate to the first semiconductor chip, the at least one first bump having a thickness in a vertical direction equal to or less than 10 μm;
a first underfill layer that fills a center portion of a space between the first substrate and the first semiconductor chip; and
a first molding member that covers an upper surface and side surfaces of the first semiconductor chip, and fills a periphery portion of the space between the first substrate and the first semiconductor chip,
wherein a volume occupied by the first molding member in the space between the first substrate and the first semiconductor chip is greater than a volume occupied by the first underfill layer in the space between the first substrate and the first semiconductor chip, and
wherein the volume occupied by the first underfill layer in the space between the first substrate and the first semiconductor chip is in a range of 5% to 50% of the space, excluding a volume of the space occupied by the at least one first bump.

12. The semiconductor package of claim 11, further comprising:
a conductive pillar on the upper surface of the first substrate and spaced apart from the first semiconductor chip in a horizontal direction;
a second substrate on an upper surface of the first molding member;
a second semiconductor chip on an upper surface of the second substrate;
at least one second bump between the second substrate and the second semiconductor chip;
a second underfill layer that fills a center portion of a space between the second substrate and the second semiconductor chip; and
a second molding member that fills a peripheral portion of the space between the second substrate and the second semiconductor chip,
wherein a distance between the upper surface of the second substrate and a lower surface of the second semiconductor chip is less than 10 μm.

13. The semiconductor package of claim 11, wherein at least a portion of the first underfill layer comprises a shape that, when the first underfill layer is viewed in the vertical direction, protrudes toward the first molding member.

14. The semiconductor package of claim 11, further comprising:
a second semiconductor chip;
an interposer substrate on the upper surface of the first substrate, wherein the first semiconductor chip and the second semiconductor chip are on an upper surface of the interposer substrate;
a second underfill layer and a second molding member between the interposer substrate and the second semiconductor chip,
wherein the first underfill layer and the first molding member are between the interposer substrate and the first semiconductor chip,
wherein the second semiconductor chip comprises a base chip and a high bandwidth memory (HBM) chip, and the HBM chip is on the base chip, and
wherein the first underfill layer overlaps with a center portion of the first semiconductor chip in the vertical direction, and the second underfill layer overlaps with a center portion of the second semiconductor chip in the vertical direction.

15. The semiconductor package of claim 11, further comprising a second semiconductor chip on an upper portion of the first semiconductor chip,
wherein the first semiconductor chip comprises a first semiconductor substrate, a first semiconductor device layer, and a through electrode that penetrates the first semiconductor substrate in the vertical direction,
wherein the second semiconductor chip comprises a second semiconductor substrate, and
wherein the first semiconductor chip is arranged so that the first semiconductor substrate faces the second semiconductor chip.

16. The semiconductor package of claim 11, wherein
each of the first molding member and the first underfill layer comprises a filler,
wherein a filler content of the first molding member is in a range of 70% to 90%, and
wherein a filler content of the first underfill layer is in a range of 5% to about 40%.

17. The semiconductor package of claim 11, wherein a footprint of the first substrate is greater than a footprint of the first semiconductor chip.

18. A semiconductor package comprising:
a first substrate comprising a wiring and an insulating layer surrounding the wiring;
a first semiconductor chip on an upper surface of the first substrate;
at least one first bump between the first substrate and the first semiconductor chip, and configured to electrically connect the first substrate to the first semiconductor chip, each of the at least one first bump having a thickness in a vertical direction equal to or less than 10 μm;
a first underfill layer that fills a center portion of a space between the first substrate and the first semiconductor chip; and
a first molding member that covers an upper surface and side surfaces of the first semiconductor chip, and fills a periphery portion of the space between the first substrate and the first semiconductor chip,
wherein each of the first molding member and the first underfill layer comprises a filler, a filler content of the first molding member is in a range of 70% to 90%, and a filler content of the first underfill layer is in a range of 5% to 40%,
wherein a volume occupied by the first molding member in the space between the first substrate and the first semiconductor chip is greater than a volume occupied by the first underfill layer, and
wherein the volume occupied by the first underfill layer in the space between the first substrate and the first semiconductor chip is in a range of 5% to 50% of the space, excluding a volume of the space occupied by the at least one first bump.

19. The semiconductor package of claim 18, further comprising:
a conductive pillar on the upper surface of the first substrate and spaced apart from the first semiconductor chip in a horizontal direction;
a second substrate on an upper surface of the first molding member;
a second semiconductor chip on an upper surface of the second substrate;
at least one second bump between the second substrate and the second semiconductor chip;
a second underfill layer that fills a center portion of a space between the second substrate and the second semiconductor chip; and
a second molding member that fills a peripheral portion of the space between the second substrate and the second semiconductor chip,
wherein a distance between the upper surface of the second substrate and a lower surface of the second semiconductor chip is less than 10 μm.

20. The semiconductor package of claim 18, further comprising:
a second semiconductor chip;
an interposer substrate on the upper surface of the first substrate, wherein the first semiconductor chip and the second semiconductor chip are on an upper surface of the interposer substrate; and
a second underfill layer and a second molding member between the interposer substrate and the second semiconductor chip,
wherein the first underfill layer and the first molding member are between the interposer substrate and the first semiconductor chip,
wherein the second semiconductor chip comprises a base chip and a high bandwidth memory (HBM) chip, and the HBM chip is on the base chip, and
wherein the first underfill layer overlaps a center portion of the first semiconductor chip in the vertical direction, and the second underfill layer overlaps a center portion of the second semiconductor chip in the vertical direction.

21-27. (canceled)
